(19) United States
(12) Patent Application Publication
(10) Pub. No.: US 2026/0040960 A1
(43) Pub. Date: Feb. 5, 2026

(54) DELAMINATION MITIGATION FOR AN INTEGRATED CIRCUIT

(71) Applicant: TEXAS INSTRUMENTS INCORPORATED, DALLAS, TX (US)

(72) Inventors: Guangxu Li, Allen, TX (US); Sylvester Ankamah-Kusi, McKinney, TX (US); Blake Travis, Richardson, TX (US); Rajen Manicon Murugan, Dallas, TX (US); Yutaka Suzuki, Allen, TX (US)

(21) Appl. No.: 18/789,114

(22) Filed: Jul. 30, 2024

(51) Int. Cl. H01L 23/495; H01L 23/00; H01L 23/31

(52) U.S. Cl. CPC H01L 23/49551; H01L 23/3107; H01L 23/4952; H01L 23/49575; H01L 24/13; H01L 24/16; H01L 2224/13147; H01L 2224/16225

(57) ABSTRACT

An electronic device includes a leadframe, where the leadframe includes inner leads, external leads, and die attach portions. The leadframe has channels defined at a junction between the die attach portions and the inner leads, where the channel mitigates crack propagation along a path of the die attach portions. A die assembly is attached to the die attach portions and copper pillars are provided to connect the die assembly to the die attach portions. A mold compound encapsulates the die assembly, the inner leads, the die attach portions, and the copper pillars.

### TECHNICAL FIELD

The present disclosure relates to electronic devices, and more specifically to electronic device having an improved design to mitigate delamination on a leadframe.

### BACKGROUND

After fabrication of electronic devices (e.g., integrated circuits (IC)), the electronic devices undergo post fabrication tests. For example, one test is comprised of a reliability test. The reliability test is a thermal test in which the electronic device is subjected to cycling temperatures. One example range may include temperatures cycling between negative 65° C. and 150° C. Unfortunately, during the temperature cycling, the material in the electronic device expand and contract at different rates due to the coefficient of thermal expansion (CTE) of each material. More specifically, a CTE mismatch between solder (e.g., solder ball), a leadframe, and mold compound will cause cracks or openings (delamination) to form between the leadframe and mold compound. The cracks can propagate toward a joint between the solder ball and leadframe, which can cause solder joint cracking thus leading to electrical failure of the electronic device.

### SUMMARY

In a described example, an electronic device includes a leadframe, where the leadframe includes inner leads, external leads, and die attach portions. A die assembly is attached to the die attach portions and interconnects connect the die assembly to the die attach portions. A mold compound encapsulates the die assembly, the inner leads, the die attach portions, and the interconnects.

In another described example, an electronic device includes a leadframe, where the leadframe includes inner leads, external leads, and die attach portions. The leadframe has channels defined at a junction between the die attach portions and the inner leads, where the channel mitigates crack propagation along a path of the die attach portions. A die assembly is attached to the die attach portions and copper pillars connect the die assembly to the die attach portions. A mold compound encapsulates the die assembly, the inner leads, the die attach portions, and the copper pillars.

In still another described example, an electronic device includes a leadframe, where the leadframe includes inner leads, external leads, and die attach portions. The die attach portions are partially etched to form a crack propagation barrier at a junction between the die attach portions and the inner leads, where the crack propagation barrier mitigates crack propagation along a path of the die attach portions. A die assembly is attached to the die attach portions and copper pillars connect the die assembly to the die attach portions. A mold compound encapsulates the die assembly, the inner leads, the die attach portions, and the copper pillars.

In still another described example, a method includes etching a channel in a leadframe at a junction defined between die attach portions and inner leads of the leadframe, where the channel mitigates crack propagation along a path defined along the die attach portions. A die assembly is attached to the die attach portions of the leadframe via interconnects. A mold compound is formed over the die assembly, the inner leads, the die attach portions, and the interconnects. T mold compound encapsulates the die assembly, the inner leads, the die attach portions, and the interconnects.

### BRIEF DESCRIPTION OF THE DRAWINGS

FIGS. 1A-1D are cross-sectional views of example electronic devices.

FIG. 2 is a cross-sectional view of another example electronic device.

FIGS. 3A and 3B are shear stress graphs illustrating a shear stress in an x-direction along a path P of die attach portions for the electronic devices of FIGS. 1A, 1B, and 2.

FIGS. 4A and 4B are normal stress graphs illustrating a normal stress in a y-direction along the path P of the die attach portions for the electronic devices of FIGS. 1A, 1B, and 2.

FIG. 5 is a block diagram flow chart explaining a fabrication process of the electronic device of FIG. 1A.

FIG. 6A is a top view of a wafer including multiple dies.

FIG. 6B illustrates a cross-sectional view of a die in the early stages of fabrication.

FIG. 6C illustrates a cross-sectional view of the die of FIG. 6B attached to a substrate to form a die assembly.

FIG. 6D illustrates a cross-sectional view of a leadframe.

FIG. 6E illustrates a cross-sectional view of the leadframe of FIG. 6D after undergoing an etching process.

FIG. 6F illustrates a cross-sectional view of the die assembly of FIG. 6C attached to the leadframe of FIG. 6E to form an electronic device.

FIG. 6G illustrates a cross-sectional view of the electronic device of FIG. 6F after undergoing a formation of a mold compound.

### DETAILED DESCRIPTION

Delamination occurs when a stress exceeds the adhesion strength between a mold compound and a leadframe in an electronic device (e.g., integrated circuit (IC)). Stresses may occur due to post fabrication tests, such as a reliability test. The reliability test is a thermal test in which the electronic device is subjected to cycling temperatures. One example range may include temperatures cycling between negative 65° C. and positive 150° C. Unfortunately, during the temperature cycling, the material in the electronic device expand and contract at different rates due to different coefficient of thermal expansion (CTE) of each material. More specifically, a CTE mismatch between solder (e.g., solder ball), a leadframe, and mold compound will cause cracks or openings (delamination) to form between the leadframe and mold compound interface. The cracks can propagate toward a joint between a solder ball and leadframe, which can cause solder joint cracking thus leading to electrical failure of the electronic device.

Disclosed herein is an electronic device and process to mitigate delamination between the leadframe and mold compound that overcomes the aforementioned delamination issues. Specifically, an inner lead of the leadframe is modified and/or a material of an interconnect connecting a die to the leadframe is changed to mitigate delamination. In one example, the inner lead of the leadframe includes an etched channel adjacent to the interconnect. The etched channel on the inner lead interrupts the propagation of cracks to mitigate delamination. In another example, the inner lead is partially etched and thus a crack propagation barrier is formed between the etched portion and the non-etched portion of the inner lead which interrupts the propagation of cracking. In still another example, the material of the interconnect is changed from a tin-based solder to copper. The CTE mismatch between the copper interconnect and the leadframe is less than that of the CTE mismatch between the solder interconnect and the leadframe. As a result, the deformation between the interconnect and leadframe is reduced, which reduces the stress between the mold compound and the leadframe thereby mitigating delamination. In still another example, the copper interconnect can be combined with the etched channel example or with the partially etched inner lead.

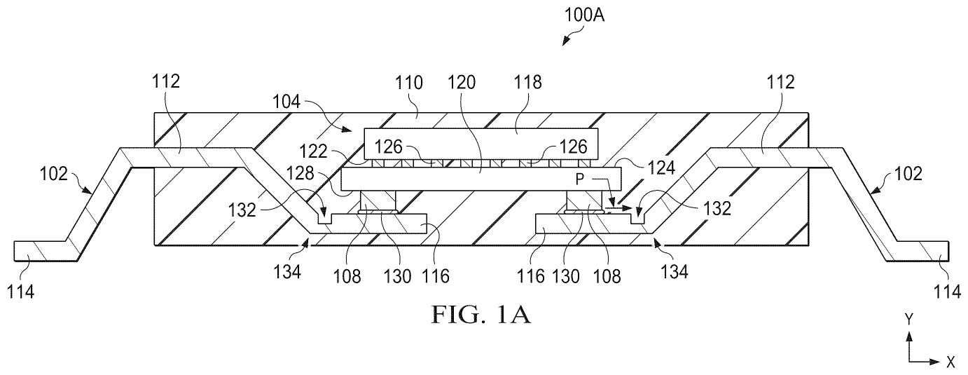

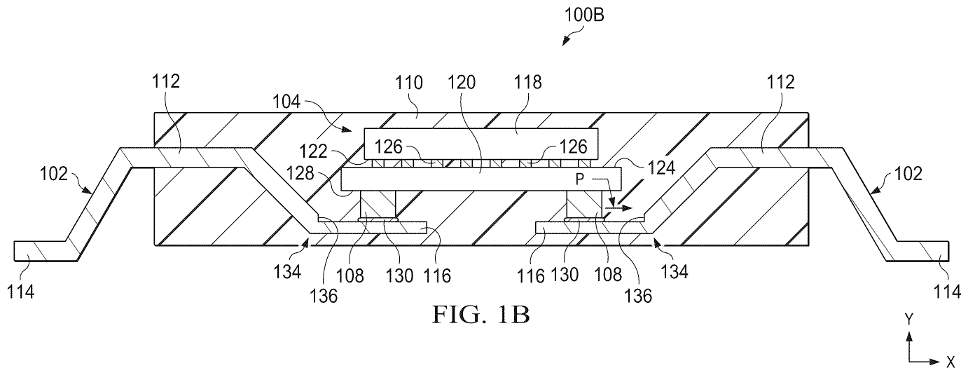

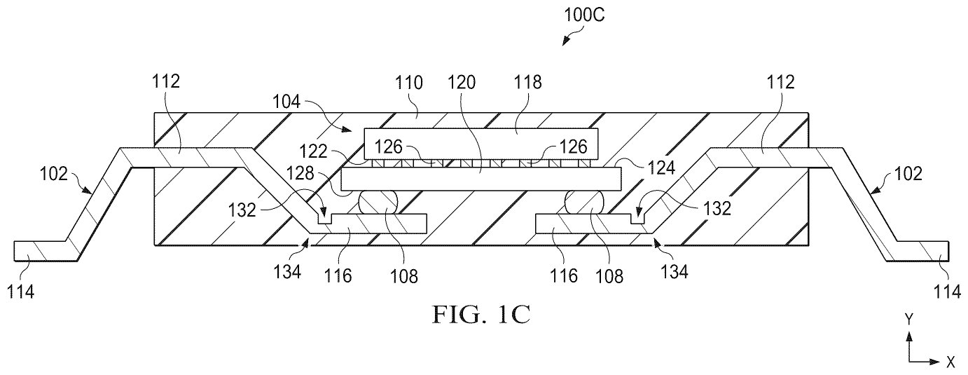

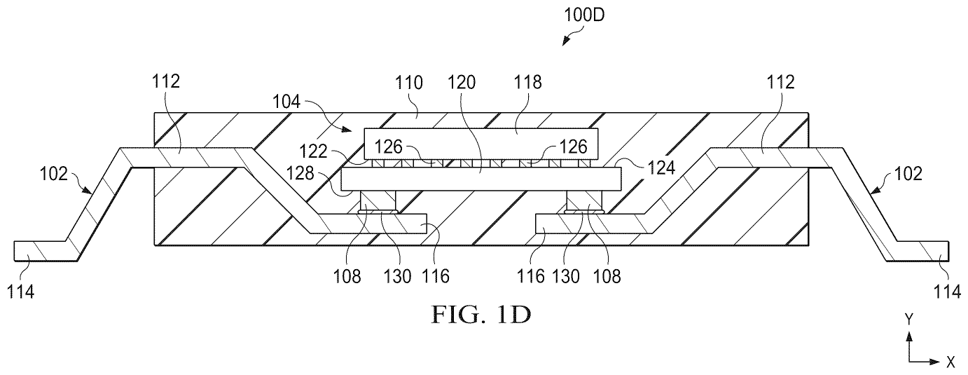

FIGS. 1A-1D are cross sectional views of example electronic devices (e.g., integrated circuits (IC)) 100A, 100B, 100C, 100D (collectively “100”). Each electronic device 100 includes a leadframe 102, a die assembly 104, interconnects (e.g., solder balls, copper pillars, etc.) 108 that connect the die assembly 104 to the leadframe 102, and a mold compound 110. The electronic device 100 can be comprised of a leaded integrated circuit (IC) including, but not limited to a Small Outline Package (SOP), Dual In-Line Package (DIP), a Single In-Line Package (SIP), etc. In addition, the electronic device 100 can be a through-hole mount or a surface mount package. Thus, the example electronic devices 100 illustrated in FIGS. 1A-1D are for illustrative purposes only and are not intended to limit the scope of the invention.

The leadframe 102 includes inner leads 112 disposed inside the mold compound 110 and outer (external) leads 114 disposed outside the mold compound 110. The leadframe 102 further includes die attach portions 116 disposed inside the mold compound 110. The die attach portions 116 extend from each inner lead 112 substantially horizontally. The die assembly 104 is comprised of one or more dies 118 and a substrate (e.g., build-up film material, copper traces and vias) 120. An active side 122 of the die 118 is attached to one (first) surface 124 of the substrate 120 via electrically conductive connectors (e.g., solder balls, copper pillars, etc.) 126. The die assembly 104 is attached to the die attach portions 116 of the leadframe 102. Specifically, an opposite (second) surface 128 of the substrate 120 of the die assembly 104 attaches to the die attach portions 116 of the of the leadframe 102 via the electrically conductive interconnects 108.

In the example illustrated in FIG. 1A, the interconnects 108 are comprised of a copper pillar and a thin (e.g., less than 15 microns) solder layer 130 disposed between the copper pillar and the die attach portions 116 of the leadframe 102. In addition, a crack mitigating feature comprising a channel 132 is etched into each die attach portion 116 of the leadframe 102 at a junction 134 between the die attach portions 116 and the inner leads 112. As explained above, the CTE mismatch between the copper pillar interconnects 108 and the leadframe 102 is less than that of the CTE mismatch between a solder interconnect and the leadframe 102. As a result, the deformation between the copper pillar interconnects 108 and leadframe 102 is reduced, which reduces the stress between the mold compound 110 and the leadframe 102 thereby mitigating delamination. In addition, since the thin solder layer 130 is less than 15 microns, the CTE mismatch between the solder and the leadframe is minimal and thus does not significantly affect any type of deformation. Still further, the etched channel 132 on the die attach portions 116 of the leadframe 102 interrupts the propagation of cracks, which in turn mitigates delamination. Finally, the presence of the channel 132 does not compromise thermal and electric properties.

The example electronic device 100B illustrated in FIG. 1B is similar to the example electronic device 100A illustrated in FIG. 1A with the exception of the die attach portions 116 of the leadframe 102. Specifically, the example electronic device 100B illustrated in FIG. 1B does not include the etched channel 132. Rather, the die attach portions 116 of the leadframe 102 is partially etched. Thus, a crack mitigating feature comprising a crack propagation barrier 136 is formed on the leadframe 102 at the junction 134 between the die attach portions 116 and the inner leads 112. The crack propagation barrier 136 mitigates the spreading of any cracks that may occur during post fabrication tests, including the reliability test described above.

The example electronic device 100C illustrated in FIG. 1C is similar to the example electronic device 100A illustrated in FIG. 1A with the exception of the material of the interconnects 108. Specifically, the interconnects 108 of the example electronic device 100C illustrated in FIG. 1C is not comprised of a copper pillar. Rather, the interconnects 108 illustrated in FIG. 1C is comprised of solder. The example electronic device 100C illustrated in FIG. 1C, however, includes the channel 132 etched into the die attach portions 116 of the leadframe 102. As mentioned above, the etched channel 132 on the die attach portions 116 of the leadframe 102 interrupts the propagation of cracks, which in turn mitigates delamination.

The example electronic device 100D illustrated in FIG. 1D is similar to the example electronic device 100A illustrated in FIG. 1A with the exception of the die attach portions 116 of the leadframe 102. Specifically, the example electronic device 100D illustrated in FIG. 1D does not include the etched channel 132. In addition, the die attach portions 116 are not partially etched. Rather, the die attach portions 116 are not modified with any type of mechanism to mitigate the propagation of cracks. The electronic device 100D, however, includes the interconnects 108 comprised of a copper pillar. As explained above, the CTE mismatch between the copper pillar interconnects 108 and the leadframe 102 is less than that of the CTE mismatch between a solder interconnect and the leadframe 102. As a result, the deformation between the copper pillar interconnects 108 and leadframe 102 is reduced, which reduces the stress between the mold compound 110 and the leadframe 102 thereby mitigating delamination. In addition, since the thin solder layer 130 is less than 15 microns, the CTE mismatch between the solder and the leadframe is minimal and thus does not significantly affect any type of deformation.

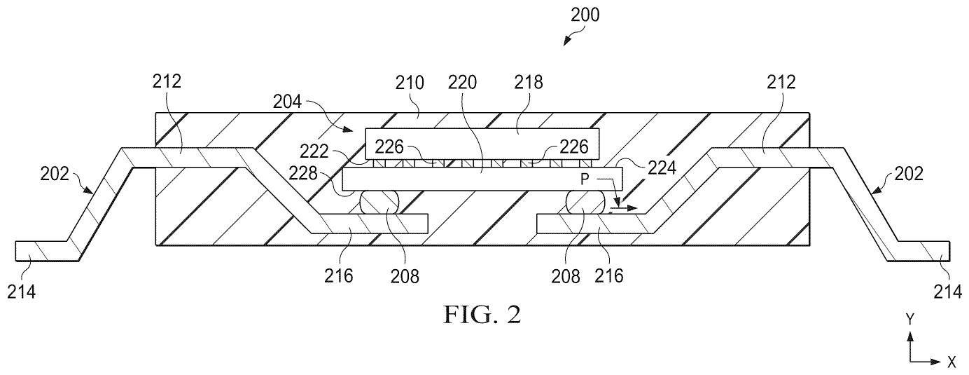

FIG. 2 is a cross-sectional view of another electronic device 200. The electronic device 200 includes a leadframe 202, a die assembly 204, interconnects (e.g., solder balls) 208 that connect the die assembly 204 to the leadframe 202, and a mold compound 210. The leadframe 202 includes inner leads 212 disposed inside the mold compound 210 and outer (external) leads 214 disposed outside the mold compound 210. The leadframe 202 further includes die attach portions 216 disposed inside the mold compound 110. The die attach portions 216 extend from each inner lead 212 substantially horizontally The die assembly 204 is comprised of one or more dies 218 and a substrate 220. An active side 222 of the die 218 is attached to one surface 224 of the substrate 220 via electrically conductive pillars (e.g., solder, copper, etc.) 226. The die assembly 204 is attached to the die attach portions 216 of the leadframe 202. Specifically, an opposite surface 228 of the substrate 220 of the die assembly 204 attaches to the die attach portions 216 of the leadframe 202 via the electrically conductive interconnects 208.

The electronic device 200, however, does not include any type of mechanism to prohibit crack propagation on the die attach portions 216 of the leadframe 202, as illustrated in FIGS. 1A-1C. In addition, the interconnects 208 in the electronic device 200 are comprised of solder and not copper pillars, as illustrated in FIGS. 1A, 1B, and 1D. As a result, the electronic device 200 illustrated in FIG. 2, is prone to crack propagation and delamination along the die attach portions 216 of the leadframe 202.

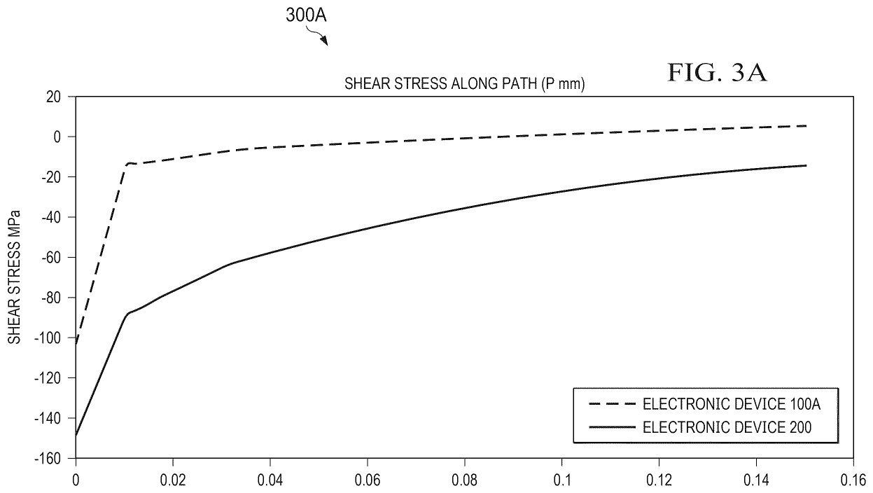

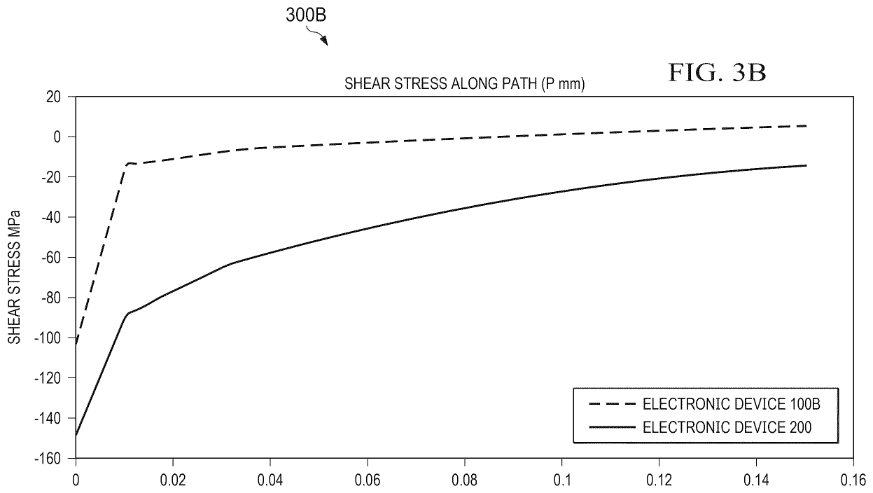

FIGS. 3A and 3B are shear stress graphs 300A, 300B illustrating a shear stress in an x-direction along a path P (see FIGS. 1A, 1B, and 2) of the die attach portions 116, 216 for the electronic devices of FIGS. 1A, 1B, and 2. FIG. 3A is a comparison of the shear stresses between the electronic devices 100A and 200 and FIG. 3B is a comparison of the shear stresses between the electronic devices 100B and 200. As illustrated, the shear stress for the electronic devices 100A and 100B shows marked improvement over the shear stress for the electronic device 200. Specifically, the shear stress for both electronic devices 100A and 100B ranges from a magnitude of approximately 100 MPa to approximately zero MPa. Whereas, the shear stress for the electronic device 200 ranges from a magnitude of approximately 160 MPa to approximately 18 MPa. As described above, the electronic device 200 has interconnects 208 comprised of solder whereas the interconnects 108 for electronic devices 100A and 100B is comprised of copper. In addition, the electronic device 200 did not include any type of crack propagation mitigation as did the electronic devices 100A and 100B.

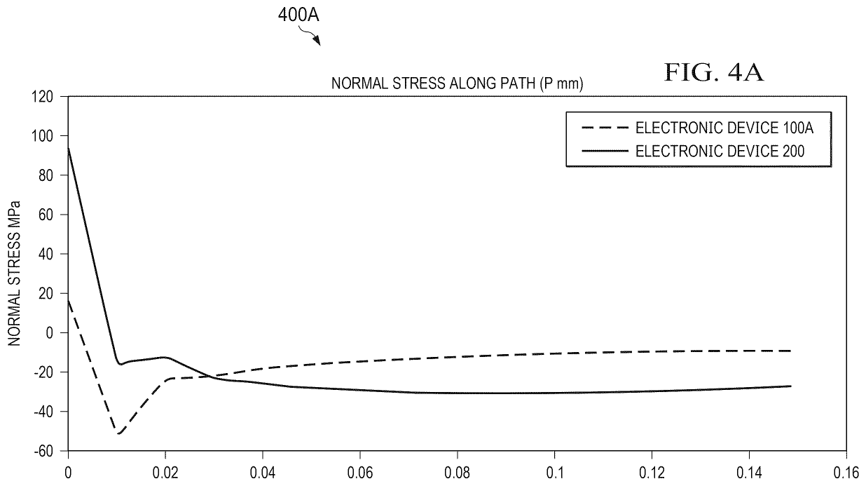

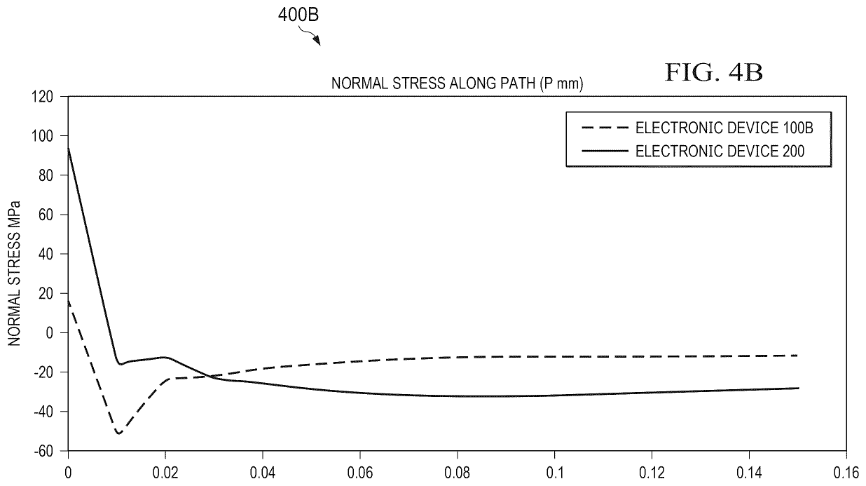

FIGS. 4A and 4B are normal stress graphs 400A, 400B illustrating a normal stress in a y-direction along the path P (see FIGS. 1A, 1B, and 2) of the die attach portions 116, 216 for the electronic devices of FIGS. 1A, 1B, and 2. FIG. 4A is a comparison of the normal stresses between the electronic devices 100A and 200 and FIG. 4B is a comparison of the normal stresses between the electronic devices 100B and 200. As illustrated, the normal stress for the electronic devices 100A and 100B shows marked improvement over the normal stress for the electronic device 200. Specifically, the normal stress for both electronic devices 100A and 100B ranges from a magnitude of approximately 20 MPa to approximately 10 MPa. Whereas, the normal stress for the electronic device 200 ranges from a magnitude of approximately 100 MPa to approximately 10 MPa. As described above, the electronic device 200 has interconnects 208 comprised of solder whereas the interconnects 108 for electronic devices 100A and 100B is comprised of copper. In addition, the electronic device 200 did not include any type of crack propagation mitigation as did the electronic devices 100A and 100B.

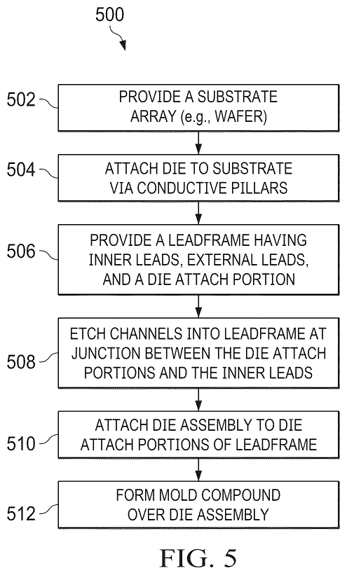

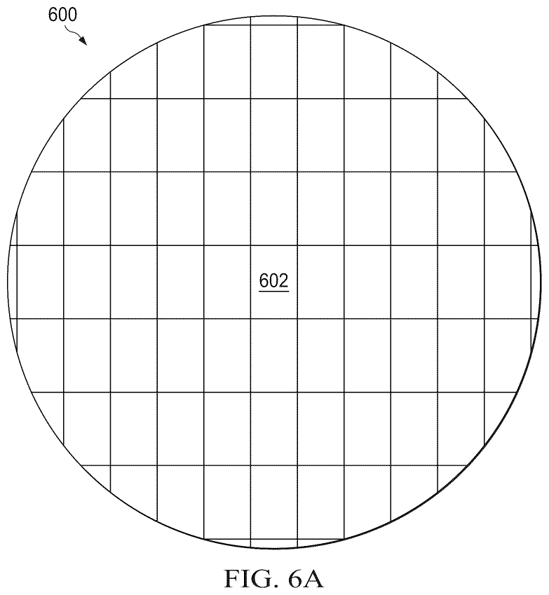

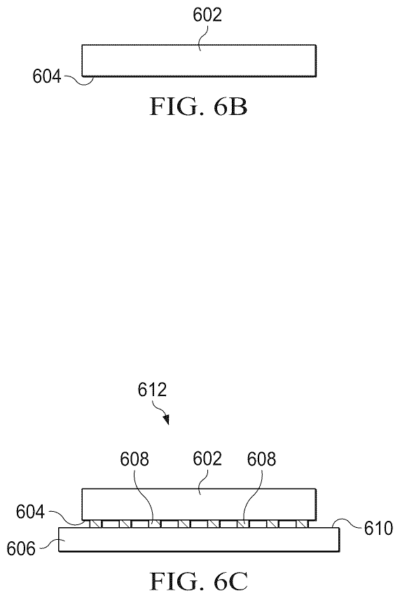

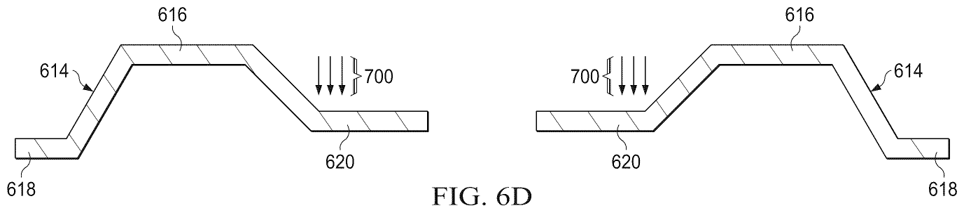

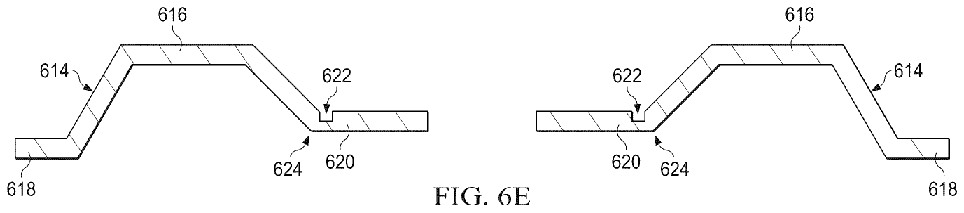

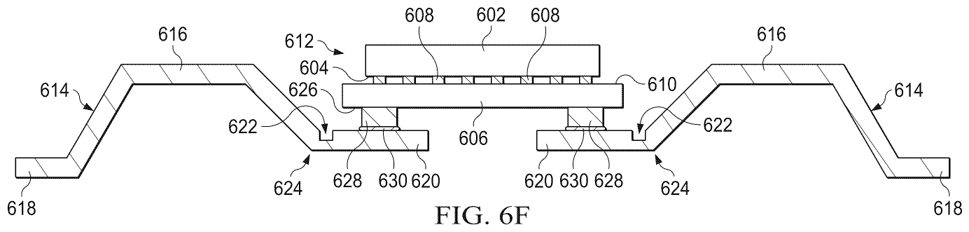

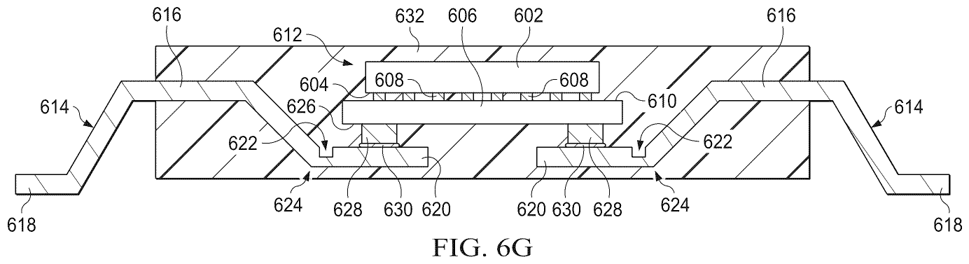

FIG. 5 is a block diagram flow chart explaining a fabrication process 500 and FIGS. 6A-6G illustrate a fabrication process associated with the formation of the electronic device 100A illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 5 and 6A-6G is an example method illustrating the example configuration of FIG. 1A, other methods and configurations are possible. It is understood that although the method illustrated in FIGS. 5 and 6A-6G depicts the fabrication process of a single electronic device, the process applies to an array of electronic devices. Thus, after fabrication of the array of electronic devices the array is singulated to separate each electronic device 100 from the array.

Referring to FIG. 5 and to FIGS. 6A-6G, the fabrication process of the electronic device 100A illustrated in FIG. 1A begins at 502 with a substrate (e.g., wafer) 600, as illustrated in FIG. 6A. Specifically, FIG. 6A is a schematic diagram of a wafer 600, in accordance with various examples. For example, the wafer 600 may be a silicon wafer. The wafer 600 comprises multiple dies 602. The manufacturing techniques described below may be performed on individual dies 602 (post-singulation), or the techniques may be more efficiently performed on a mass scale, e.g., simultaneously on multiple dies 602 of the wafer 600 (pre-singulation). For convenience and clarity, the remaining drawings show one die 602, with the understanding that the processes described herein as being performed on the die 602 may also be performed (e.g., sequentially performed, simultaneously performed) on the remaining dies 602 of the wafer 600.

FIG. 6B illustrates a cross sectional view of a single die 602 of the wafer 600 where the die 602 includes an active side 604. At 504, the die 602 is attached to a substrate 606 via electrically conductive connectors (e.g., solder balls, copper pillars, etc.) 608. Specifically, the active side 604 of the die 602 is attached to a first surface 610 of the substrate 606 via the electrically conductive connectors 608 resulting in a die assembly 612 illustrated in the configuration of FIG. 6C. At 506, a leadframe 614 is provided where the leadframe 614 includes inner leads, 616, external leads 618, and die attach portions 620. At 508, the leadframe 614 illustrated in FIG. 6D undergoes an etching process 700 to etch channels 622 in the die attach portions 620 at a junction 624 between the die attach portions 620 and the inner leads 616 resulting in the configuration of FIG. 6E. Alternatively, in the example electronic device 100B illustrated in FIG. 1B, the die attach portions 620 of the leadframe 614 would undergo a partial etching process to partially etch the entire die attach portions 620. At 510, the die assembly 612 is attached to the die portions 620 of the leadframe 614. Specifically, a second surface 626 of the substrate is attached to the die attach portions 620 via interconnects 628. In the example illustrated in FIG. 6F, the interconnects 628 are comprised of copper pillars and a thin layer (e.g., less than 15 microns) of solder 630 is disposed between the copper pillars 628 and the die attach portions 620 for adhesive purposes. In an alternative example, the interconnects 628 can be comprised of solder. At 512, a mold compound 632 is formed over and encapsulates the die assembly 612, the die attach portions 620, the inner leads 616, and the interconnects 628.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe, the leadframe including inner leads, external leads, die attach portions, and a crack mitigating feature;
a die assembly attached to the die attach portions;
interconnects connecting the die assembly to the die attach portions; and
a mold compound encapsulating the die assembly, the inner leads, the die attach portions, and the interconnects.

2. The electronic device of claim 1, wherein the crack mitigating feature includes channels in the leadframe at a junction between the die attach portions and the inner leads, the channel mitigating crack propagation along a path of the die attach portions.

3. The electronic device of claim 1, wherein the die attach portions are partially etched to form a crack propagation barrier at a junction between the die attach portions and the inner leads, the crack propagation barrier mitigating crack propagation along a path of the die attach portions.

4. The electronic device of claim 1, wherein the interconnects comprise copper pillars.

5. The electronic device of claim 4 further comprising a solder layer disposed between the copper pillars and the die attach portions.

6. The electronic device of claim 5, wherein the solder layer is less than 15 microns thick.

7. The electronic device of claim 1, wherein the die assembly comprises a die and a substrate, the die having an active side, the active side of the die being connected to a first surface of the substrate via electrically conductive connectors.

8. The electronic device of claim 7, wherein the electrically conductive connectors comprise copper connectors.

9. An electronic device comprising:
a leadframe, the leadframe including inner leads, external leads, and die attach portions, the leadframe having channels defined therein at a junction between the die attach portions and the inner leads, the channel mitigating crack propagation along a path of the die attach portions;
a die assembly attached to the die attach portions;
copper pillars connecting the die assembly to the die attach portions; and
a mold compound encapsulating the die assembly, the inner leads, the die attach portions, and the copper pillars.

10. The electronic device of claim 9, wherein the die assembly comprises a die and a substrate, the die having an active side, the active side of the die being connected to a first surface of the substrate via electrically conductive connectors.

11. The electronic device of claim 10, wherein the electrically conductive connectors comprise copper connectors.

12. The electronic device of claim 9 further comprising a solder layer disposed between the copper pillars and the die attach portions.

13. The electronic device of claim 12, wherein the solder layer is less than 15 microns thick.

14. An electronic device comprising:
a leadframe, the leadframe including inner leads, external leads, and die attach portions, the die attach portions being partially etched to form a crack propagation barrier at a junction between the die attach portions and the inner leads, the crack propagation barrier mitigating crack propagation along a path of the die attach portions;
a die assembly attached to the die attach portions;
copper pillars connecting the die assembly to the die attach portions; and
a mold compound encapsulating the die assembly, the inner leads, the die attach portions, and the copper pillars.

15. The electronic device of claim 14, wherein the die assembly comprises a die and a substrate, the die having an active side, the active side of the die being connected to a first surface of the substrate via electrically conductive connectors.

16. The electronic device of claim 15, wherein the electrically conductive connectors comprise copper connectors.

17. The electronic device of claim 14 further comprising a solder layer disposed between the copper pillars and the die attach portions.

18. The electronic device of claim 17, wherein the solder layer is less than 15 microns thick.

19. A method comprising:
etching a channel in a leadframe at a junction defined between die attach portions and inner leads of the leadframe, the channel mitigating crack propagation along a path defined along the die attach portions;
attaching a die assembly to the die attach portions of the leadframe via interconnects; and
forming a mold compound over the die assembly, the inner leads, the die attach portions, and the interconnects, the mold compound encapsulating the die assembly, the inner leads, the die attach portions, and the interconnects.

20. The method of claim 19, wherein prior to attaching a die assembly to the die attach portions of the leadframe via interconnects, the method includes attaching an active side of a die to a substrate via electrically conductive connectors to form the die assembly.

21. The method of claim 19, wherein the interconnects comprise copper pillars.
